(19) United States
(12) Patent Application Publication
(10) Pub. No.: US 2023/0005977 A1
(43) Pub. Date: Jan. 5, 2023

(54) IMAGE SENSING DEVICE

(71) Applicant: SK hynix Inc., Icheon-si (KR)

(72) Inventor: Yun Hui Yang, Icheon-si (KR)

(21) Appl. No.: 17/582,475

(22) Filed: Jan. 24, 2022

(30) Foreign Application Priority Data
Jun. 30, 2021 (KR) 10-2021-0086027

(51) Int. Cl. H01L 27/146

(52) U.S. Cl. CPC H01L 27/14621; H01L 27/14645; H01L 27/1463

(57) ABSTRACT

An image sensing device includes a substrate layer including a plurality of photoelectric conversion elements configured to generate photocharges, a plurality of color filters disposed over the substrate layer, a metal layer disposed between the color filters adjacent to each other, a buffer layer disposed over the metal layer, an air layer disposed over the buffer layer, and a capping layer formed to cover a stacked structure of the metal layer, the buffer layer, and the air layer. A region of the capping layer that covers the air layer is formed to have a larger thickness than the other regions of the capping layer that cover the metal layer and the buffer layer.

### CROSS-REFERENCE TO RELATED APPLICATION

This patent document claims the priority and benefits of Korean patent application No. 10-2021-0086027, filed on Jun. 30, 2021, which is incorporated by reference in its entirety as part of the disclosure of this patent document.

### TECHNICAL FIELD

The technology and implementations disclosed in this patent document generally relate to an image sensing device.

### BACKGROUND

An image sensing device is used in electronic devices to convert optical images into electrical signals. With the recent development of automotive, medical, computer and communication industries, the demand for highly integrated, higher-performance image sensors has been rapidly increasing in various electronic devices such as digital cameras, camcorders, personal communication systems (PCSs), video game consoles, surveillance cameras, medical micro-cameras, and robots.

### SUMMARY

Various embodiments of the disclosed technology relate to an image sensing device that can minimize the risk of collapse of a grid structure that includes different material layers with different thermal expansion coefficients.

In an embodiment of the disclosed technology, an image sensing device may include a substrate layer including a plurality of photoelectric conversion elements configured to detect incident light to generate photocharges, a plurality of color filters disposed over the substrate layer to filter the incident light toward the plurality of photoelectric conversion elements depending on a wavelength range of the incident light corresponding to colors of the incident light, a metal layer disposed between the color filters adjacent to each other, a buffer layer disposed over the metal layer between the color filters adjacent to each other, an air layer disposed over the buffer layer between the color filters adjacent to each other, and a capping layer formed to cover a stacked structure of the metal layer, the buffer layer, and the air layer, wherein a region of the capping layer that covers the air layer is formed to have a larger thickness than the other regions of the capping layer that cover the metal layer and the buffer layer.

In another embodiment of the disclosed technology, an image sensing device may include a substrate layer including a plurality of photoelectric conversion elements and device isolation structures disposed between the photoelectric conversion elements, wherein the photoelectric conversion elements are configured to detect incident light to generate photocharges, and the device isolation structures are configured to electrically or optically isolate the photoelectric conversion elements from each other, a first material layer disposed over the substrate to overlap with the device isolation structure and having a first thermal expansion coefficient, a second material layer disposed over the first material layer and having a second thermal expansion coefficient smaller than the first thermal expansion coefficient, a third material layer disposed over the second material layer and having a third thermal expansion coefficient smaller than the second thermal expansion coefficient, and a capping layer structured to cover a stacked structure of the first material layer, the second material layer, and the third material layer. In some implementations, the second material layer may have a top surface that includes one or more protruding regions and one or more recess region.

In another embodiment of the disclosed technology, an image sensing device may include a substrate layer including a plurality of photoelectric conversion elements configured to detect incident light to generate photocharges, a plurality of color filters disposed over the substrate layer to filter the incident light toward the plurality of photoelectric conversion elements depending on a wavelength range of the incident light corresponding to colors of the incident light, and a plurality of grid structures disposed between adjacent color filters. Each of the grid structures include a metal layer, a buffer layer disposed over the metal layer, an enclosed region over the buffer layer as an air layer, a first capping layer structured to cover a top surface and a side surface of the air layer, and a second capping layer structured to cover a side surface of the metal layer and a side surface of the buffer layer. The buffer layer has a thermal expansion coefficient that is lower than the metal layer and higher than the air layer. In some implementations, the second material layer may have a top surface that includes one or more protruding regions and one or more recess region. In some implementations, the first capping layer is thicker than the second capping layer.

In another embodiment of the disclosed technology, an image sensing device may include a substrate layer including a plurality of photoelectric conversion elements configured to generate photocharges through conversion of incident light, a plurality of color filters formed over the substrate layer, a metal layer disposed between the color filters adjacent to each other in the color filters, a buffer layer disposed over the metal layer, an air layer disposed over the buffer layer, and a capping layer formed to cap or cover a stacked structure of the metal layer, the buffer layer, and the air layer, wherein a region contacting the air layer from among the capping layer is formed to have a larger thickness than another region contacting the metal layer and the buffer layer.

In another embodiment of the disclosed technology, an image sensing device may include a substrate layer including a plurality of photoelectric conversion elements configured to generate photocharges through conversion of incident light, and a device isolation structure disposed between the photoelectric conversion elements, a first material layer disposed over the substrate to overlap with the device isolation structure, and configured to have a first thermal expansion coefficient, a second material layer stacked over the first material layer, and configured to have a second thermal expansion coefficient smaller than the first thermal expansion coefficient, a third material layer stacked over the second material layer, and configured to have a third thermal expansion coefficient smaller than the second thermal expansion coefficient, and a capping layer formed to contact the first material layer, the second material layer, and the third material layer, and formed to cap or cover a stacked structure of the first material layer, the second material layer, and the third material layer. The second material layer may be provided with a top surface formed in a concavo-convex shape.

In another embodiment of the disclosed technology, an image sensing device may include a substrate layer structured to support a plurality of photoelectric conversion elements configured to detect incident light to generate photocharges carrying image information in the incident light, a plurality of color filters disposed over the substrate layer to filter the incident light toward the plurality of photoelectric conversion elements depending on a wavelength range of the incident light corresponding to colors of the incident light, a metal layer disposed between the color filters adjacent to each other, a buffer layer disposed over the metal layer between the color filters adjacent to each other, and a capping layer formed to cover a stacked structure of the metal layer and the buffer layer and structured to include capping layer portions between the color filters that are spaced away from the buffer layer so as to form an air layer between the buffer layer and the capping layer to separate adjacent color filters. In some implementations, a region of the capping layer that covers the air layer is formed to have a larger thickness than the other regions of the capping layer that cover the metal layer and the buffer layer.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

FIG. 1 is a block diagram illustrating an example of an image sensing device based on some implementations of the disclosed technology.

FIG. 2 is a cross-sectional view illustrating an example of a pixel array taken along the line X-X′ shown in FIG. 1 based on some implementations of the disclosed technology.

FIG. 3 illustrates how differences in the thermal expansion coefficients of an air layer and a metal layer that are in direct contact with each other in a grid structure can cause collapse of the grid structure.

FIGS. 4A to 4D are cross-sectional views illustrating methods for forming the grid structure shown in FIG. 2 based on some implementations of the disclosed technology.

FIG. 5 is a cross-sectional view illustrating another example of the pixel array taken along the line X-X′ shown in FIG. 1 based on some implementations of the disclosed technology.

FIGS. 6A to 6F are cross-sectional views illustrating methods for forming the grid structure shown in FIG. 5 based on some implementations of the disclosed technology.

FIGS. 7A and 7B are cross-sectional views illustrating other examples of the pixel array taken along the line X-X′ shown in FIG. 1 based on some implementations of the disclosed technology.

FIGS. 8A and 8B are cross-sectional views illustrating examples of photoresist patterns for forming a buffer layer shown in FIGS. 7A and 7B based on some implementations of the disclosed technology.

### DETAILED DESCRIPTION

This patent document provides implementations and examples of an image sensing device and the disclosed features may be implemented to achieve one or more advantages in more applications. Some implementations of the disclosed technology suggest designs of an image sensing device structured to minimize collapse of a grid structure that includes different material layers with different thermal expansion coefficients, by adding a buffer layer that can reinforce the stability of the grid structure which includes different material layers with different thermal expansion coefficients.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

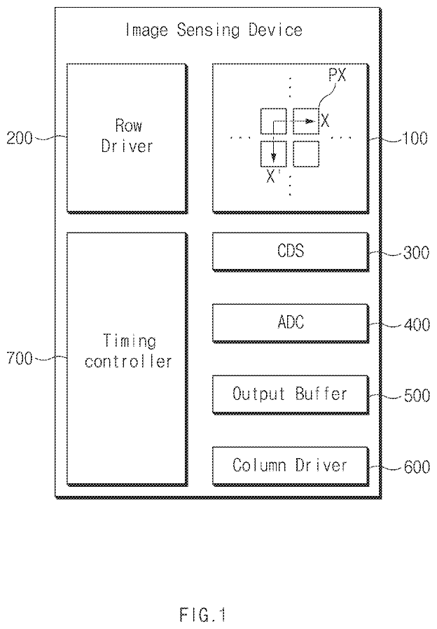

FIG. 1 is a block diagram illustrating an image sensing device based on some implementations of the disclosed technology.

Referring to FIG. 1, the image sensing device may include a pixel array 100, a row driver 200, a correlated double sampler (CDS) 300, an analog-digital converter (ADC) 400, an output buffer 500, a column driver 600 and a timing controller 700. The components of the image sensing device illustrated in FIG. 1 are discussed by way of example only, and this patent document encompasses numerous other changes, substitutions, variations, alterations, and modifications.

The pixel array 100 may include a plurality of unit pixels (PXs) consecutively arranged in row and column directions. Each unit pixel (PX) may generate a pixel signal corresponding to incident light through conversion of the incident light. In this case, each unit pixel (PX) may include a photoelectric conversion element for converting incident light into photocharges, and a plurality of switching elements (e.g., a transfer transistor, a reset transistor, a source follower transistor, and a selection transistor) for outputting a pixel signal by reading out the photocharges received from the photoelectric conversion element. In addition, each unit pixel (PX) may include any one of a red color filter, a green color filter, and a blue color filter, and the unit pixels (PXs) may be arranged in a Bayer pattern. A grid structure for preventing crosstalk of the incident light may be disposed between the color filters of the unit pixels (PXs) adjacent to each other.

The pixel array 100 may receive driving signals (for example, a row selection signal, a reset signal, a transmission (or transfer) signal, etc.) from the row driver 200. Upon receiving the driving signal, the unit pixels may be activated to perform the operations corresponding to the row selection signal, the reset signal, and the transfer signal.

The row driver 200 may activate the pixel array 100 to perform certain operations on the unit pixels in the corresponding row based on control signals provided by controller circuitry such as the timing controller 700. In some implementations, the row driver 200 may select one or more pixel groups arranged in one or more rows of the pixel array 100. The row driver 200 may generate a row selection signal to select one or more rows from among the plurality of rows. The row driver 200 may sequentially enable the reset signal and the transfer signal for the unit pixels arranged in the selected row. The pixel signals generated by the unit pixels arranged in the selected row may be output to the correlated double sampler (CDS) 300.

The correlated double sampler (CDS) 300 may remove undesired offset values of the unit pixels using correlated double sampling. In one example, the correlated double sampler (CDS) 300 may remove the undesired offset values of the unit pixels by comparing output voltages of pixel signals (of the unit pixels) obtained before and after photocharges generated by incident light are accumulated in the sensing node (i.e., a floating diffusion (FD) node). As a result, the CDS 300 may obtain a pixel signal generated only by the incident light without causing noise. In some implementations, upon receiving a clock signal from the timing controller 700, the CDS 300 may sequentially sample and hold voltage levels of the reference signal and the pixel signal, which are provided to each of a plurality of column lines from the pixel array 100. That is, the CDS 300 may sample and hold the voltage levels of the reference signal and the pixel signal which correspond to each of the columns of the pixel array 100. In some implementations, the CDS 300 may transfer the reference signal and the pixel signal of each of the columns as a correlate double sampling (CDS) signal to the ADC 400 based on control signals from the timing controller 700.

The ADC 400 is used to convert analog CDS signals received from the CDS 300 into digital signals. In some implementations, the ADC 400 may be implemented as a ramp-compare type ADC. The analog-to-digital converter (ADC) 400 may compare a ramp signal received from the timing controller 700 with the CDS signal received from the CDS 300, and may thus output a comparison signal indicating the result of comparison between the ramp signal and the CDS signal. The analog-to-digital converter (ADC) 400 may count a level transition time of the comparison signal in response to the ramp signal received from the timing controller 700, and may output a count value indicating the counted level transition time to the output buffer 500.

The output buffer 500 may temporarily store column-based image data provided from the ADC 400 based on control signals of the timing controller 170. The image data received from the ADC 400 may be temporarily stored in the output buffer 500 based on control signals of the timing controller 700. The output buffer 500 may provide an interface to compensate for data rate differences or transmission rate differences between the image sensing device and other devices.

The column driver 600 may select a column of the output buffer 500 upon receiving a control signal from the timing controller 700, and sequentially output the image data, which are temporarily stored in the selected column of the output buffer 500. In some implementations, upon receiving an address signal from the timing controller 700, the column driver 600 may generate a column selection signal based on the address signal, may select a column of the output buffer 500 using the column selection signal, and may control the image data received from the selected column of the output buffer 500 to be output as an output signal.

The timing controller 700 may generate signals for controlling operations of the row driver 200, the ADC 400, the output buffer 500 and the column driver 600. The timing controller 700 may provide the row driver 200, the column driver 600, the ADC 400, and the output buffer 500 with a clock signal required for the operations of the respective components of the image sensing device, a control signal for timing control, and address signals for selecting a row or column. In some implementations, the timing controller 700 may include a logic control circuit, a phase lock loop (PLL) circuit, a timing control circuit, a communication interface circuit and others.

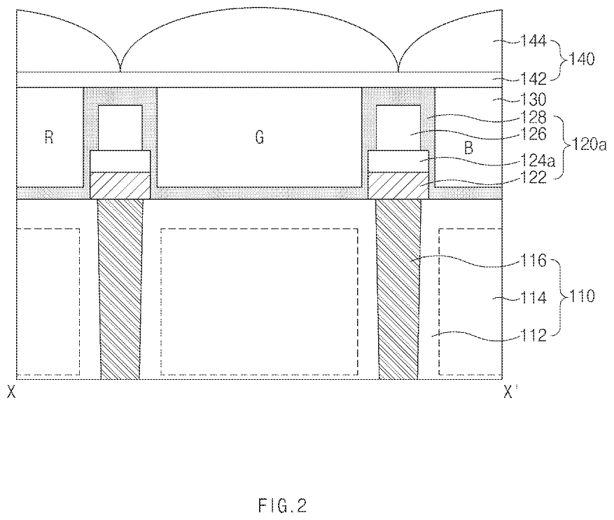

FIG. 2 is a cross-sectional view illustrating an example of the pixel array 100 taken along the line X-X′ shown in FIG. 1 based on some implementations of the disclosed technology.

Referring to FIG. 2, the pixel array 100 may include a substrate layer 110, a grid structure 120a, a color filter layer 130, and a lens layer 140.

The substrate layer 110 may include a substrate 112, a plurality of photoelectric conversion elements 114, and a plurality of device isolation structures 116. The substrate layer 110 may include a first surface and a second surface. In some implementations, one of the first and second surfaces is the top surface of the substrate layer 110 and the other of the first and second surfaces is the bottom surface of the substrate layer 110. In some implementations, the lens layer 140 and the color filter layer 130 are arranged over the first surface, and the light incident on the lens layer 140 at the first surface of the substrate layer 110 is directed toward the photoelectric conversion elements 114.

The substrate 112 may include a semiconductor substrate including a monocrystalline silicon material. The substrate 112 may include P-type impurities.

The photoelectric conversion elements 114 may be formed in the semiconductor substrate 112. In some implementations, each of the unit pixels (PXs) includes a photoelectric conversion element 114. The photoelectric conversion elements 114 may be formed in a region that is defined by the device isolation structures 116 in each unit pixel (PX). The photoelectric conversion elements 114 may convert incident light (e.g., visible light) filtered by the color filter layer 130 into electric charges (e.g., photocharges). Each of the photoelectric conversion elements 114 may include N-type impurities.

Each of the device isolation structures 116 may be formed between photoelectric conversion elements 114 of the adjacent unit pixels arranged in the substrate 112 to isolate the photoelectric conversion elements 114 from each other. The device isolation structures 116 may include a trench structure such as a Back Deep Trench Isolation (BDTI) structure or a Front Deep Trench Isolation (FDTI) structure. Alternatively, each of the device isolation structures 116 may include a junction isolation structure formed by implanting a large amount of impurities (e.g., P-type impurities) into the semiconductor substrate 112, creating a doping profile that has a relatively heavier doping concentration.

The grid structure 120a may be located at a boundary region between the adjacent color filters (R, G, B) 130 to prevent crosstalk between the adjacent color filters (R, G, B) 130. The grid structure 120a may be formed over the first surface of the substrate layer 110. The grid structure 120a may be formed over the device isolation structures 116 to vertically overlap with the device isolation structures 116. The grid structure 120a may include a metal layer 122, a buffer layer 124a, an air layer 126, and a capping layer 128.

In some implementations, the metal layer 122 may include tungsten (W). In some implementations, a barrier metal layer (not shown) may be additionally disposed below the metal layer 122. In one example, the barrier metal layer and the metal layer 122 can be stacked on top of one another. In one example, the barrier metal layer 122 may include at least one of titanium (Ti) or titanium nitride (TiN). In another example, the barrier metal layer 122 may include a stacked structure of titanium (Ti) and titanium nitride (TiN).

In some implementations of the disclosed technology, the capping layer 128 above the buffer layer 124a is structured to include protruded capping layer portions between the color filters 130 that are spaced away from the buffer layer 124a so as to form a void or space that is filled with air as an air layer 126 between the buffer layer 124a and the capping layer 128 to separate adjacent color filters 130. Therefore, the buffer layer 124a is positioned between the air layer 126 and the metal layer 122 (e.g., over the metal layer 122 and below the air layer 126) such that at least part of the buffer layer 124a vertically overlaps with the metal layer 122. The buffer layer 124a may be formed to prevent or reduce thermo-mechanical stresses on the capping layer 128 that can be generated by the thermal expansion mismatch between the metal layer 122 and the air layer 126. In some implementations of the disclosed technology, the buffer layer 124a can have a thermal expansion coefficient that is higher than the metal layer 122 and lower than the air layer 126. In addition, the disclosed technology can be implemented in some embodiments to create a large interfacial area between the buffer layer 124a and the capping layer 128, thereby exhibiting improved structural stability.

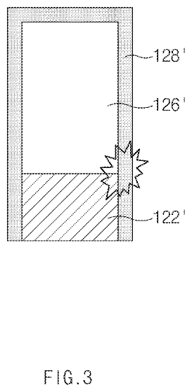

FIG. 3 illustrates how differences in the thermal expansion coefficients of the air layer and the metal layer that are in direct contact with each other in the grid structure can cause collapse of the grid structure.

Referring to FIG. 3, a grid structure in some implementations may include a metal layer 122′ and an air layer 126′ that are in direct contact with each other, and a capping layer 128′ is formed to cover the metal layer 122′ and the air layer 126′. However, a thermal stress created by temperature changes may be concentrated on the capping layer 128′ at a boundary region where the metal layer 122′ is in contact with the air layer 126′ due to a difference in thermal expansion coefficient between the metal layer 122′ and the air layer 126′ in a high-temperature condition such as a thermal annealing process.

The thermal stress concentrated on a specific region of the capping layer 128′ can create a crack in the specific region, resulting in collapse of the capping layer 128′.

The disclosed technology can be implemented in some embodiments to provide, between the metal layer and the air layer, a buffer structure that can reduce the structural deformation of the grid structure caused by the difference in thermal expansion coefficients between the metal layer and the air layer. In this case, the buffer layer 124a may include a material having a thermal expansion coefficient that is between a thermal expansion coefficient of the metal layer 122 and a thermal expansion coefficient of the air layer 126. For example, the buffer layer 124a may include an oxide layer or a nitride layer.

The air layer 126 may be formed over the buffer layer 124a such that at least part of the air layer 126 vertically overlaps with the metal layer 122 and the buffer layer 124a. In some implementations, the air layer 126 may be smaller in width than the buffer layer 124a. In some implementations, the center portion of the air layer 126 may be formed to vertically overlap with the center portion of the buffer layer 124a. For example, the center of the horizontal cross-section of the air layer 126 may be aligned with the center of the horizontal cross-section of the buffer layer 124a. In some implementations, the air layer 126 may be smaller in width than the buffer layer 124a.

The capping layer 128 may be an outer layer of the grid structure 120a that covers the metal layer 122, the buffer layer 124a, and the air layer 126. The capping layer 128 may include an oxide layer. The oxide layer may include an ultra-low temperature oxide (ULTO) film such as a silicon oxide film (SiO₂). The capping layer 128 may extend to a region below the color filter layer 130. This portion of the capping layer 128 formed below the color filter layer 130 may be used as an anti-reflection layer that compensates for a difference in refractive index between the color filter layer 130 and the substrate 112, so that more light rays having penetrated the color filter layer 130 can reach the substrate 112.

However, since a region contacting the air layer 126 in the capping layer 128 may not have a material capable of supporting this region, the region is more vulnerable to impact applied from the outside as compared to the other region contacting either the metal layer 122 or the buffer layer 124a, so that the region vulnerable to such impact can be easily collapsed.

In some implementations, the region of the capping layer 128 that covers the air layer 126 may be formed to be thicker than the other regions of the capping layer 128 that cover either the metal layer 122 or the buffer layer 124a. The thicker region of the capping layer 128, which covers the air layer 126, may also increase the size of a contact region between the capping layer 128 and the buffer layer 124a, so that the capping layer 128 can be more firmly supported by the buffer layer 124a. In this way, the structural stability of the capping layer 128 may increase.

The color filter layer 130 may include color filters (R, G, B) that filter certain wavelengths of incident light that passes through the lens layer 140 and transmit the filtered light to the corresponding photoelectric conversion elements 114. The color filter layer 130 may include a plurality of red color filters (Rs), a plurality of green color filters (Gs), and a plurality of blue color filters (Bs). Each red color filter (R) may transmit visible light having a first wavelength band corresponding to red light. Each green color filter (G) may transmit visible light having a second wavelength band shorter than the first wavelength band, corresponding to green light. Each blue color filter (B) may transmit visible light having a third wavelength band shorter than the second wavelength band, corresponding to blue light. The color filters (R, G, B) may be formed over the substrate layer 110 in a region defined by the grid structure 120a.

The lens layer 140 may include an over-coating layer 142 and a plurality of microlenses 144. The over-coating layer 142 may be formed over the grid structure 120a and the color filter layer 130. The over-coating layer 142 may operate as a planarization layer for planarization of the grid structure 120a and the color filter layer 130. The microlenses 144 may be formed over the over-coating layer 142. Each of the microlenses 144 may be formed in a hemispherical shape, and may be formed per unit pixel (PX). The microlenses 144 may converge incident light, and may transmit the converged light to the photoelectric conversion elements 114 through the corresponding color filters R, G, and B. The over-coating layer 142 and the microlenses 144 may include the same materials.

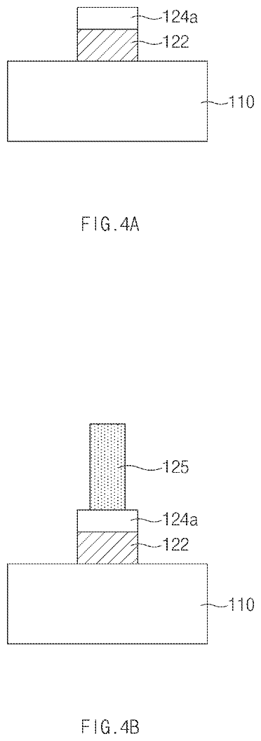

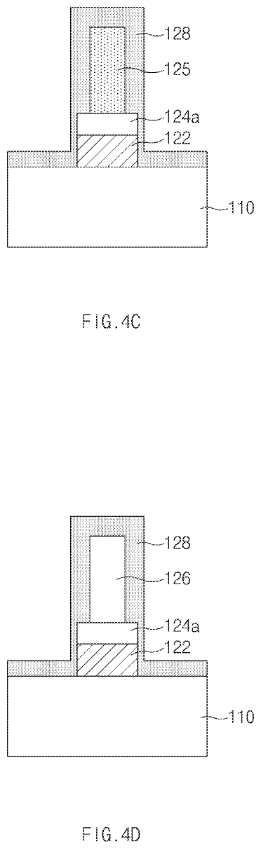

FIGS. 4A to 4D are cross-sectional views illustrating methods for forming the grid structure shown in FIG. 2 based on some implementations of the disclosed technology.

Referring to FIG. 4A, the metal layer 122 and the buffer layer 124a may be sequentially stacked over the substrate layer 110 that includes photoelectric conversion elements and a device isolation structure.

The metal layer 122 and the buffer layer 124a can be formed in the following steps. First, a metal material is formed over the substrate layer 110. The oxide layer is then formed over the metal material. Subsequently, an etching/patterning process is performed on the metal material and the oxide layer using a mask pattern such as a photoresist pattern (not shown) defining a grid structure region as an etch mask. Here, the metal layer 122 may include tungsten (W). In some implementations, the barrier metal layer may be formed below the metal layer 122.

Referring to FIG. 4B, a sacrificial film pattern 125 may be formed over the buffer layer 124a in a region where the air layer 126 will be formed.

For example, after a sacrificial film (not shown) is formed over the structure of FIG. 4A, a mask pattern such as a photoresist pattern (not shown) defining the region of the air layer 126 may be formed over the sacrificial film. In some implementations, the sacrificial film may include a carbon-containing Spin On Carbon (SOC) film.

Subsequently, the sacrificial film may be etched and patterned using the mask pattern as an etch mask, so that the sacrificial film pattern 125 can be formed over the buffer layer 124a. In this case, the sacrificial film pattern 125 may be formed to have a smaller width than the buffer layer 124a.

Referring to FIG. 4C, the capping layer 128 may be formed over the substrate layer 110, the metal layer 122, the buffer layer 124a, and the sacrificial film pattern 125.

In some implementations, the sacrificial film pattern 125 may have a smaller width than each of the metal layer 122 and the buffer layer 124a, so that a region of the capping layer 128 that is in contact with the sacrificial film pattern 125 is thicker than the other regions that are in contact with either the metal layer 122 or the buffer layer 124a. In addition, the region of the capping layer 128 that is in contact with the sacrificial film pattern 125 may also be in contact with a top surface of the buffer layer 124a, so that the size of a contact region between the capping layer 128 and the buffer layer 124a can increase.

In this case, the capping layer 128 may include an Ultra-Low Temperature Oxide (ULTO) film. In some implementations, the capping layer 128 may be formed to a predetermined thickness through which molecules generated from the sacrificial film pattern 125 can be easily discharged outside.

Referring to FIG. 4D, a plasma process may be carried out upon the resultant structure of FIG. 4C. The sacrificial film pattern 125 may be removed and the air layer 126 may be formed at the position from which the sacrificial film pattern 125 is removed.

In some implementations, the plasma process may be carried out using gas (e.g., O₂, N₂, Hz, CO, CO₂, or CH₄) including at least one of oxygen, nitrogen, or hydrogen.

Referring to FIG. 4C, if the 02 plasma process is carried out upon the resultant structure of FIG. 4C, oxygen radicals (0*) may flow into the sacrificial film pattern 125 through the capping layer 128, and the oxygen radicals (O*) may be combined with carbons of the sacrificial film pattern 125, forming CO or CO₂. The formed CO or CO₂ may be discharged outside through the capping layer 128.

As a result, the sacrificial film pattern 125 can be removed, and the air layer 126 may be formed at the position where the sacrificial film pattern 125 is removed.

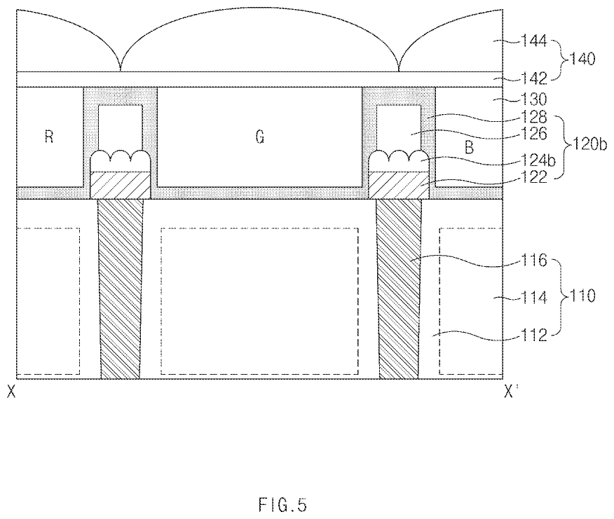

FIG. 5 is a cross-sectional view illustrating another example of the pixel array taken along the line X-X′ shown in FIG. 1 based on some implementations of the disclosed technology.

FIG. 5 illustrates a grid structure 120b different from the grid structure 120a illustrated in FIG. 2. In some implementations, all the layers in FIG. 5 have the same structure as all the layers in FIG. 2, except for the grid structure 120a or 120b.

The grid structure 120b may include the metal layer 122, the buffer layer 124b, the air layer 126, and the capping layer 128.

Unlike the buffer layer 124a shown in FIG. 2, the buffer layer 124b may be formed in a three-dimensional (3D) structure that includes one or more concave structures and/or one or more convex structures. In some implementations, the buffer layer 124b may have a top surface that includes one or more protruding regions and one or more recess regions. For example, the top surface of the buffer layer 124b may be formed in a shape in which convex structures (e.g., hemispherical structures) are consecutively arranged.

As described above, the top surface of the buffer layer 124b is formed to have an uneven surface, so that the contact region between the buffer layer 124b and the capping layer 128 shown in FIG. 5 may be larger in size than the contact region between the buffer layer 124a and the capping layer 128 shown in FIG. 2.

Although FIG. 5 illustrates each buffer layer as including three hemispherical structures for convenience of description, it should be noted that more than three hemispherical structures can be formed so that the capping layer 128 can be in contact with the plurality of small-sized hemispherical structures.

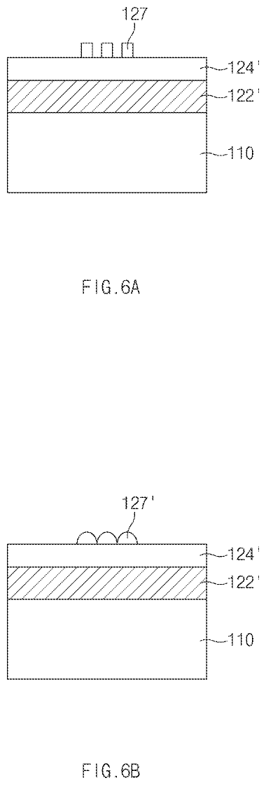

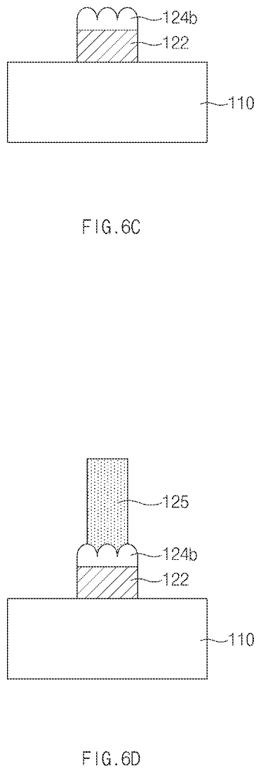

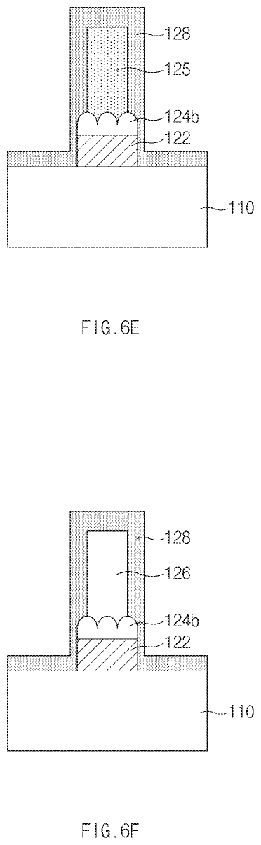

FIGS. 6A to 6F are cross-sectional views illustrating methods for forming the grid structure shown in FIG. 5 based on some implementations of the disclosed technology.

Referring to FIG. 6A, a metal layer 122′ and an oxide layer 124′ may be sequentially stacked on the substrate layer 110 including photoelectric conversion elements and a device isolation structure.

Subsequently, a photoresist pattern 127 may be disposed over the oxide layer 124′, so that the photoresist pattern 127 is formed in a region where the grid structure will be formed. For example, after a photoresist material layer (not shown) is formed over the oxide layer 124′, the photoresist material layer may be patterned by an exposure and development process, forming the photoresist pattern 127.

Referring to FIG. 6B, a flow process is performed on the photoresist pattern 127, resulting in formation of a hemispherical photoresist pattern 127′.

Referring to FIG. 6C, after an upper portion of the oxide layer 124′ is etched using the photoresist pattern 127′ as an etch mask, the metal layer 122′ and the remaining regions of the oxide layer 124′ may be etched using a mask pattern (not shown) for isolating the metal layer 122′. In this way, the buffer layer 124b having a top surface that includes one or more protruding regions and one or more recess regions is formed, and the metal layer 122 is also formed.

Referring to FIG. 6D, the sacrificial film pattern 125 may be formed over the buffer layer 124b in a region where the air layer 126 will be formed.

For example, after a sacrificial film (not shown) is formed over the structure of FIG. 6C, a mask pattern such as a photoresist pattern (not shown) defining the region of the air layer 126 may be formed over the sacrificial film. In this case, the sacrificial film may include a carbon-containing Spin On Carbon (SOC) film. Subsequently, the sacrificial film may be etched and patterned using the mask pattern as an etch mask, so that the sacrificial film pattern 125 can be formed over the buffer layer 124b. In some implementations, the sacrificial film pattern 125 may be formed to have a smaller width than the buffer layer 124b.

Referring to FIGS. 6E and 6F, after the capping layer 128 is formed over the substrate layer 110, the metal layer 122, the buffer layer 124b, and the sacrificial film pattern 125 as shown in FIGS. 4C and 4D, a plasma process may be carried out upon the resultant structure of FIG. 6E. In this way, the sacrificial film pattern 125 may be removed and the air layer 126 may be formed at the position from which the sacrificial film pattern 125 is removed.

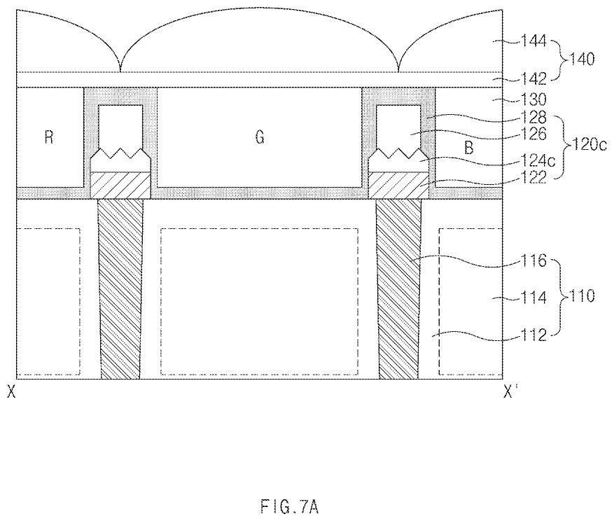

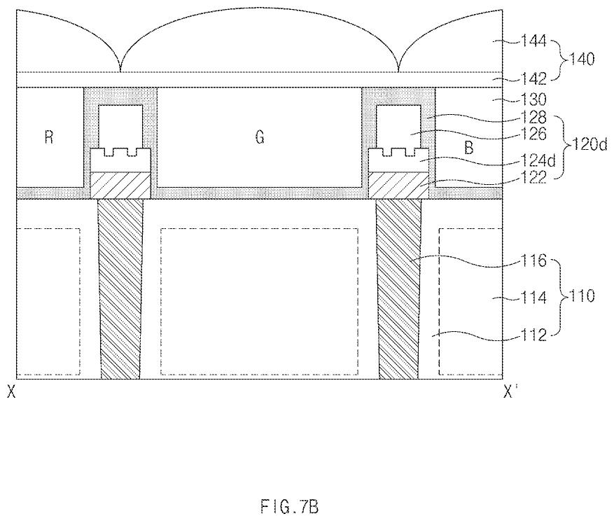

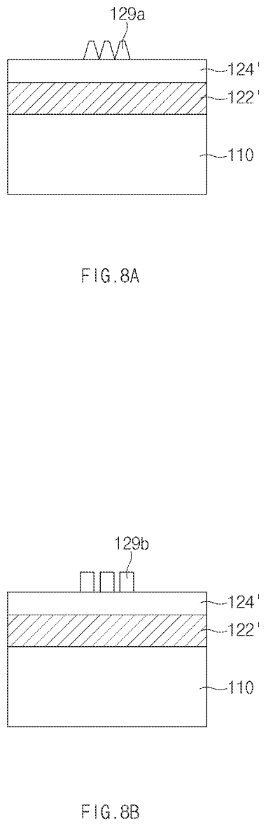

FIGS. 7A and 7B are cross-sectional views illustrating other examples of the pixel array taken along the line X-X′ shown in FIG. 1 based on some implementations of the disclosed technology. FIGS. 8A and 8B are cross-sectional views illustrating examples of photoresist patterns for forming the buffer layer shown in FIGS. 7A and 7B based on some implementations of the disclosed technology.

In the grid structure, the top surface of the buffer layer formed between the metal layer 122 and the air layer 126 may be formed in a three-dimensional (3D) shape different from the hemispherical shape shown in FIG. 5. For example, the buffer layer may have a top surface that has a serrated shape as shown in FIG. 7A or a square shape as shown in FIG. 7B.

A method for forming the buffer layer 124c shown in FIG. 7A may include adjusting a fabrication condition in a manner that the photoresist pattern is formed to have a predetermined slope when the photoresist pattern is formed over the oxide layer 124′, forming the photoresist pattern 129a as show in FIG. 8A by adjusting the fabrication condition, and performing the etch process shown in FIG. 6C, forming the buffer layer 124c.

In addition, a method for forming the buffer layer 124d shown in FIG. 7B may include forming a box-shaped photoresist pattern 129b shown in FIG. 8B over the oxide layer 124′, and performing the etch process shown in FIG. 6C, forming the buffer layer 124d as shown in FIG. 7B.

As is apparent from the above description, the image sensing device based on some implementations of the disclosed technology can minimize the risk of collapse of the grid structure that includes different material layers with different thermal expansion coefficients.

Although a number of illustrative embodiments have been described, it should be understood that various modifications to the disclosed embodiments and other embodiments can be devised based on what is described and/or illustrated in this patent document.

What is claimed is:

1. An image sensing device comprising:
a substrate layer including a plurality of photoelectric conversion elements configured to detect incident light to generate photocharges;
a plurality of color filters disposed over the substrate layer to filter the incident light toward the plurality of photoelectric conversion elements depending on a wavelength range of the incident light corresponding to colors of the incident light;
a metal layer disposed between the color filters adjacent to each other;
a buffer layer disposed over the metal layer between the color filters adjacent to each other;
an air layer disposed over the buffer layer between the color filters adjacent to each other; and
a capping layer formed to cover a stacked structure of the metal layer, the buffer layer, and the air layer,
wherein a region of the capping layer that covers the air layer is formed to have a larger thickness than the other regions of the capping layer that cover the metal layer and the buffer layer.

2. The image sensing device according to claim 1, wherein:
the capping layer is formed to cover a top surface and a side surface of the air layer, a side surface of the metal layer, a side surface of the buffer layer, and a portion of a top surface of the buffer layer.

3. The image sensing device according to claim 1, wherein:
the air layer is formed to have a smaller width than the buffer layer.

4. The image sensing device according to claim 1, wherein:
the buffer layer has a top surface that includes one or more protruding regions and one or more recess regions.

5. The image sensing device according to claim 4, wherein:
the one or more protruding regions have hemispherical shapes.

6. The image sensing device according to claim 4, wherein:
the one or more protruding regions and one or more recess regions form a serrated shape.

7. The image sensing device according to claim 4, wherein:
the one or more protruding regions and one or more recess regions have square shapes.

8. The image sensing device according to claim 1, wherein:
the buffer layer includes a material that has a thermal expansion coefficient between a thermal expansion coefficient of the metal layer and a thermal expansion coefficient of the air layer.

9. The image sensing device according to claim 1, wherein:
the capping layer is formed to extend to a region disposed below the color filters.

10. The image sensing device according to claim 1, wherein:
the capping layer includes an ultra-low temperature oxide (ULTO) film.

11. An image sensing device comprising:
a substrate layer including a plurality of photoelectric conversion elements and device isolation structures disposed between the photoelectric conversion elements, wherein the photoelectric conversion elements are configured to detect incident light to generate photocharges, and the device isolation structures are configured to electrically or optically isolate the photoelectric conversion elements from each other;
a first material layer disposed over the substrate layer to overlap with the device isolation structure and having a first thermal expansion coefficient;
a second material layer disposed over the first material layer and having a second thermal expansion coefficient smaller than the first thermal expansion coefficient;
a third material layer disposed over the second material layer and having a third thermal expansion coefficient smaller than the second thermal expansion coefficient; and
a capping layer structured to cover a stacked structure of the first material layer, the second material layer, and the third material layer,
wherein the second material layer has a top surface that includes one or more protruding regions and one or more recess regions.

12. The image sensing device according to claim 11, wherein:
the one or more protruding regions have hemispherical shapes.

13. The image sensing device according to claim 11, wherein:
the one or more protruding regions and one or more recess regions form a serrated shape.

14. The image sensing device according to claim 11, wherein:
the one or more protruding regions and one or more recess regions have square shapes.

15. The image sensing device according to claim 11, wherein:
the capping layer is in contact with at least a portion of the top surface of the second material layer that includes one or more protruding regions and one or more recess regions.

16. The image sensing device according to claim 11, wherein:
a region of the capping layer that covers the third material layer is formed to have a larger thickness than the other regions of the capping layer that cover the first material layer and the second material layer.

17. The image sensing device according to claim 11, wherein:
the first material layer includes metal; and
the third material layer includes air.

18. An image sensing device comprising:
a substrate layer including a plurality of photoelectric conversion elements configured to detect incident light to generate photocharges;
a plurality of color filters disposed over the substrate layer to filter the incident light toward the plurality of photoelectric conversion elements depending on a wavelength range of the incident light corresponding to colors of the incident light; and
a plurality of grid structures disposed between adjacent color filters, each of the grid structures including a metal layer, a buffer layer disposed over the metal layer, an enclosed region over the buffer layer as an air layer, a first capping layer structured to cover a top surface and a side surface of the air layer, and a second capping layer structured to cover a side surface of the metal layer and a side surface of the buffer layer,
wherein the buffer layer has a thermal expansion coefficient that is lower than the metal layer and higher than the air layer.

19. The image sensing device according to claim 18, wherein the buffer layer has a top surface that includes one or more protruding regions and one or more recess regions.

20. The image sensing device according to claim 18, wherein the first capping layer is thicker than the second capping layer.
